(19) United States
(12) Patent Application Publication
(10) Pub. No.: US 2025/0266322 A1
(43) Pub. Date: Aug. 21, 2025

(54) SUBSTRATE COMPRISING VIAS AND ASSOCIATED MANUFACTURING METHODS

(71) Applicants: COMMISSARIAT A L'ENERGIE ATOMIQUE ET AUX ENERGIES ALTERNATIVES, Paris (FR); SOITEC, Bernin (FR)

(72) Inventors: Jean CHARBONNIER, Grenoble Cedex 09 (FR); Perceval COUDRAIN, Grenoble Cedex 09 (FR); Caroline COUTIER, Grenoble Cedex 09 (FR); Bruno GHYSELEN, Seyssinet Pariset (FR); Thierry SALVETAT, Grenoble Cedex 09 (FR)

(73) Assignees: COMMISSARIAT A L'ENERGIE ATOMIQUE ET AUX ENERGIES ALTERNATIVES, Paris (FR); SOITEC, Bernin (FR)

(21) Appl. No.: 18/854,415

(22) PCT Filed: Mar. 28, 2023
(86) PCT No.: PCT/EP2023/057901

§ 371 Date: Oct. 4, 2024

(30) Foreign Application Priority Data
Apr. 6, 2022 (FR) 2203158

(51) Int. Cl. H01L 23/48; H01L 21/768

(52) U.S. Cl. CPC H01L 23/481; H01L 21/76898

(57) ABSTRACT

A substrate is provided, including: a first layer based on a semiconductive material; a second layer surmounting the first layer; and a plurality of buried vias extending from the second layer over a portion of the first layer, each via of the plurality of buried vias being delimited by a side wall, a bottom wall, and an upper wall opposite the bottom wall, at least one assembly of the plurality of vias forming a pattern repeated along at least one direction of a main extension plane of the first layer and the second layer. A method for manufacturing the substrate is also provided. A method for manufacturing a microelectronic device is also provided.

### TECHNICAL FIELD OF THE INVENTION

The present invention relates to the field of substrates intended to manufacture electronic devices and, more specifically, microelectronic devices. These substrates can ultimately enable an electrical and mechanical connection of electrical elements of components. The invention has an advantageous, but not limiting, application in manufacturing microelectronic devices.

### PRIOR ART

There is an interest in manufacturing microelectronic devices by using vias extending perpendicularly to the main extension plane of the substrate. This can be particularly interesting for manufacturing electromechanical microsystems (MEMS, MicroElectroMechanical Systems). This can further be particularly interesting for manufacturing assemblies of components on substrates comprising vias to form through contacts in order to be able to inter-connect these components on the front face and on the back face of a substrate, to obtain a microelectronic device. The components can thus be connected to a printed circuit, for example, through a casing. These substrates can, in particular, be semiconductive substrates, for example of the semiconductor-on-insulator type, and in particular, silicon-on-insulator (SOI) type.

The etching and the filling of these vias (commonly called TSV (Through-Silicon-Via) with an electrically conductive or semiconductive material, are quite specific steps of the method and often produced at assemblers' premises (commonly called OSAT (Outsourced Semi-conductor Assembly and Test) and not at founders' premises.

Two types of vias are distinguished according to their time of manufacture in the production line of a microelectronic device. So-called “TSV-middle” vias are generally manufactured in the middle of the method, after manufacturing patterns of a component during the Front-end-of-line (FEOL), but before depositing the metal layers of the Back-end-of-line (BEOL). This generally demands a transfer of the substrate and of the components from the founder to the assembler to manufacture vias, then a return to the founder for the BEOL steps, and finally also, a transfer to the assembler to finalise the method. These manufacturing steps are very limited in terms of planarity, of contamination, which is not very compatible with these back-and-forth motions between founder and assembler.

“TSV-last” vias can be manufactured at the end of the method, after the FEOL and BEOL steps. This generally demands one single transfer from the founder to the assembler, after the BEOL steps. However, the via geometries which can thus be achieved are limited. In particular, the via density being able to be obtained is limited.

There is therefore a need to obtain these structures without depending on the other manufacturing steps of the line.

An aim of the present invention is therefore to facilitate the manufacture of vias in a microelectronic device.

Other aims, features and advantages of the present invention will appear upon examining the description below and the accompanying drawings. It is understood that other advantages can be incorporated.

### SUMMARY OF THE INVENTION

To achieve this aim, according to a first aspect, a substrate is provided, in particular for a microelectronic device, comprising:
a first base layer, and preferably made of a semiconductive material,
a second layer surmounting the first layer.

The substrate comprises a plurality of buried vias extending from the second layer over a portion of the first layer, each via being delimited by a side wall, a bottom wall, and an upper wall opposite the bottom wall, and at least one assembly of the plurality of vias forms a pattern repeated along at least one direction of the main extension plane of the first and second layers.

Thus, the substrate is generic and comprises non-opening vias, previously filled or configured for filling with a subsequent electrically or semiconductive conductor member. This makes it possible to provide the vias independently of the other steps of producing a microelectronic device. The substrate comprising the buried vias can be used to carry out the deposition of layers, for example from the FEOL or from the BEOL, then the vias can be used to produce the desired electrically conductive or semiconductive member, for example, electrical interconnections. Furthermore, with the vias being manufactured beforehand, the geometries of the vias are not limited.

The substrate comprises a via matrix that it is possible to totally or partially select, in order to the produce the desired electrically conductive or semiconductive members, at most adapted from the desired geometry. The generic substrate comprising these vias therefore makes it possible to facilitate the manufacture of the vias and of the conductive or semiconductive member, in particular by being able to be adapted to different microelectronic devices.

It is therefore understood that manufacturing the vias is facilitated, in particular regarding the other steps of manufacturing a microelectronic device, by making it possible to be adapted to different microelectronic devices, with one same generic substrate. Manufacturing the vias filled with the electrically conductive or semiconductive member, is more particularly facilitated.

A second aspect relates to a method for manufacturing the substrate, comprising:
a provision of a support sub-substrate comprising at least one first layer based on a semiconductive material, the support sub-substrate having an exposed surface,
the formation of a plurality of vias, such that the vias extend from the exposed surface over a portion of the first layer, each via being delimited by a side wall and a bottom wall, at least one via assembly forming a pattern repeated along at least one direction of the main extension plane of the first and second layers,
a provision of a donor sub-substrate comprising a superficial layer having an exposed surface,
an assembly of the support sub-substrate and of the donor sub-substrate by their exposed surfaces, so as to cover the vias, each via thus being delimited by the side wall, the bottom wall, and an upper wall opposite the bottom wall.

This method thus enables the manufacturing of the buried via matrix on the substrate. This method has the effects and advantages described relative to the first aspect.

A third aspect relates to a method for manufacturing a microelectronic device comprising:
a provision of a substrate according to the first aspect and/or of a substrate manufactured by the method according to the second aspect, having a front exposed surface and a back exposed surface,
a formation of at least one layer portion of the device by a deposition of said portion, on at least one from among the front or back exposed surfaces of the substrate, for example, a first exposed surface, and for example, the front exposed surface, and/or an etching of at least one from among the front or back exposed surfaces of the substrate, for example, the first exposed surface, and for example, the front exposed surface, configured so as to form said portion,
at the at least one via, an etching by one from among the front or back exposed surfaces of the substrate, for example, a second exposed surface distinct from the first, and for example, the back exposed surface, until reaching the via, and:
   continuing the etching to reach the at least one layer portion of the device, or
   at the at least one via, an etching by the other from among the front or back exposed surfaces of the substrate, for example, by the first exposed surface, and for example, the front exposed surface, until reaching the via,
the deposition of at least one electrically conductive or semiconductive member, so as to provide electrical continuity to at least the via and the device layer portion, for example further with the front and/or back surface of the substrate.

Thus, the substrate provided enables the formation of a microelectronic device, then the opening of buried vias to produce the desired electrically conductive or semiconductive member. This can be produced in a facilitated manner with respect to the current solutions.

### BRIEF DESCRIPTION OF THE FIGURES

The aims, objectives, as well as the features and advantages of the invention will best emerge from the detailed description of an embodiment of the latter, which is illustrated by the following accompanying drawings, in which:

FIGS. 1A and 1B respectively represent transverse cross-sectional and cross-sectional views in the main extension plane of the first and second layers, of the substrate according to an example of an embodiment.

FIGS. 2A to 2C represent cross-sectional views of different via configurations.

FIGS. 3A and 3B respectively represent transverse cross-sectional and cross-sectional views in the main extension plane of the first and second layers, of the substrate according to another example of an embodiment.

FIGS. 4A to 4E represent transverse cross-sectional views of the steps of the method for manufacturing the substrate according to an example of an embodiment.

FIGS. 5A to 5D represent transverse cross-sectional views of the steps of the method for manufacturing the substrate according to another example of an embodiment.

FIGS. 6A to 6D represent transverse cross-sectional views of the steps of the method for manufacturing the microelectronic device according to an example of an embodiment.

FIGS. 7 and 8A to 8D represent transverse cross-sectional views of the steps of the method for manufacturing the microelectronic device according to two other examples of embodiments.

FIGS. 9A to 9C represent transverse cross-sectional views of the steps of the method for manufacturing the microelectronic device according to an example in which a via comprises several portions, each having a different configuration.

The drawings are given as examples and are not limiting of the invention. They constitute principle schematic representations intended to facilitate the understanding of the invention, and are not necessarily to the scale of practical applications. In particular, the relative dimensions of the sub-substrates and substrate, of the layers, of the vias and of the walls are not representative of reality.

### DETAILED DESCRIPTION OF THE INVENTION

Before starting a detailed review of embodiments of the invention, optional features are stated below which can optionally be used in association or alternatively.

According to an example, for at least some of the vias, and for example, for each via, the vias are at least partially filled with material(s).

According to an example, each via has at least one transverse dimension of between 1 μm and 30 μm. According to an example, all the transverse dimensions of each via are between 1 μm and 30 μm.

According to an example, at least some of the vias, and preferably each via, has an aspect ratio greater than or equal to 10, of longer dimensions oriented along a dimension in thickness of the first and second layers. This form factor is particularly adapted to obtain a great via density on the substrate, and in particular in synergy with the pitch value ranges stated below.

According to an example, within a via assembly, two via patterns, for example two vias, repeated successively, are separated by a following constant pitch of at least one direction of the main extension plane of the first and second layers.

According to an example, the pitch is substantially between 50 μm and 300 μm, preferably between 100 μm and 200 μm. This pitch enables a better via density in the substrate. Thus, a greater interconnecting density is possible. Furthermore, the adaptability of the substrate to different microelectronic devices is improved.

According to an example, the substrate comprises several via assemblies, each forming a pattern repeated along at least one direction of the main extension plane of the first and second layers. The generic substrate can thus comprise different via pattern arrangements to be adapted to varied microelectronic devices.

According to an example, at least one via, and preferably at least some of the plurality of vias, and preferably each via, has at least one via configuration, in which:
the side wall of the via is made of a dielectric material, and the via is filled with an electrically conductive or semiconductive material or the via is hollow,
the side wall of the via is made of a dielectric material, and the via is filled with the material of the first layer,
the side wall of the via is made of the material of the first layer and the via is hollow.

The vias can therefore be solid or hollow, and optionally already electrically isolated from the first layer. When the side wall of the via is made of a dielectric material, the vias formed in the substrate have a dielectric layer at least on their side wall, prior to using the substrate in a method for manufacturing a microelectronic device. The wall made of dielectric material being formed beforehand, it enables a good isolation of the vias once filled with the conductive or semiconductive material, while being compatible with the FEOL steps or of temporary mounting of a support.

According to an example, at least one via, and preferably at least some of the plurality of vias, and preferably each via of at least one assembly, has a first via configuration on a first portion, and a second via configuration, distinct from the first via configuration on a second portion, the first and second portions extending successively along a dimension in thickness of the first and second layers. According to an example, a portion of these vias can be hollow, and another portion can be solid. This via type makes it possible to make via widths narrower for the solid portion, and therefore more vias on the given surface. Their accessibility is made easier by the hollow portion already formed.

According to an example, the substrate comprising several via assemblies, each forming a pattern repeated along at least one direction of the main extension plane of the first and second layers, at least one assembly, and preferably each assembly, has at least one via configuration, distinct from another assembly. The generic substrate can thus comprise different via structures to be adapted to varied microelectronic devices.

According to an example, the substrate further comprises a system configured so as to enable the alignment of the substrate. This makes it possible to also facilitate the manufacturing of the microelectronic device, by facilitating the alignment of the substrate, and in particular, for producing photolithographic steps necessary for the FEOL and BEOL construction, and therefore, the opening of the vias.

According to an example, the vias are parallel to one another.

According to an example, the vias have a longitudinal dimension oriented along a dimension in thickness of the first and of the second layer.

According to an example, the vias extend along a direction parallel to the normal of the main extension plane of the first and second layers.

According to an example, at least some of the vias, and preferably each via of the at least one assembly, have a transverse cross-section, for example, in a plane substantially parallel to the main extension plane of the first and second layers, square-, polygonal- or cylindrical-shaped.

According to an example, the second layer surmounts the first layer being directly in contact with it.

According to an example, at least some of the vias, and preferably each via, has a transverse cross-section, for example, in a plane substantially parallel to the main extension plane of the first and second layers, the ratio of the largest dimension over the smallest dimension of which is less than or equal to 3, preferably less than or equal to 2. The vias are therefore absolutely distinguished from other structures such as trenches.

According to an example, at least some of the vias, and preferably each via of the at least one assembly, has a symmetry of revolution about an axis substantially parallel to a dimension in thickness of the first and second layers. Preferably, at least some of the vias, and preferably each via of at least one assembly, is cylindrical. Thus, the bottom wall of the vias is more homogeneous than for non-cylindrical shapes, for example, a square shape for which the corners will be shallower than the centre, following the etching of the vias. A cylindrical shape minimises this effect. Furthermore, the mechanical stresses are lower for cylindrical vias which do not have the singularities of the corners. It is advantageous for the heat treatment during the manufacturing of the circuits.

According to an example, at least one via, and preferably each via of at least one assembly, on at least one portion of a longitudinal dimension of said via, is fully surrounded by a groove extending from the second layer over a portion of the first layer. The groove makes it possible to improve the electrical isolation between the vias. The groove is thus manufactured beforehand and independently of the other steps of manufacturing the microelectronic device. The groove is thus compatible with the FEOL steps taking place at a high temperature. Furthermore, with the groove being manufactured beforehand, its geometry is not limited by the other steps of manufacturing the microelectronic device.

According to an example, each groove is not filled with a solid material. Each groove is preferably filled with an electrically isolating gaseous atmosphere, for example, air.

According to an example, each groove is delimited by a bottom wall, a side wall and an upper wall opposite the bottom wall. For at least one groove, and preferably for each groove, at least one part of the side wall and the bottom wall can be made of the same material as that of the first layer. The isolation of the vias is indeed sufficient, thanks to the isolating atmosphere contained in the groove. Alternatively, for at least one groove, and preferably for each groove, at least one part of the side wall and the bottom wall can be made of dielectric material, for example, the same dielectric material as the walls of the via. Thus, the electrical isolation of the via is also improved.

According to an example, the groove is concentric to said via. This makes it possible, in particular, to decrease the interfering capacity between the via and the substrate, and to increase the breakdown voltage.

According to an example, the groove extends from the second layer into the first layer over a longitudinal dimension less than a longitudinal dimension of the via, preferably the longitudinal dimension of the groove is less than or equal to the longitudinal dimension of the via, preferably, plus or minus 5 μm. Thus, the groove surrounds the via on at least one portion and preferably substantially the entire longitudinal dimension.

According to an example, the semiconductive material is chosen from among the group consisting of silicon Si, germanium Ge, SiGe, a Ill-V material (for example, GaN, InN, InGaAs, GaP, InP, InAs, AsGa, etc.), a II-VI material, wide band gap materials, for example, greater than 3 eV.

According to an example, the semiconductive material comprises, and preferably is, silicon.

According to an example, the piezoelectric material is chosen from among lithium tantalate (LiTaO₃), lithium niobate (LiNbO₃), potassium sodium niobate (KₓNa₁₋ₓNbO₃ or KNN), barium titanate (BaTiO₃), quartz, lead zirconate titanate (PZT), a lead magnesium and lead titanate niobate compound (PMN-PT), zinc oxide (ZnO), aluminium nitride (AlN) or aluminium scandium nitride (AlScN).

According to an example, the dielectric material is a semiconductive oxide, and preferably silica of chemical formula SiO₂.

According to an example of the method for manufacturing the substrate, the formation of the plurality of vias is configured such that at least some of the plurality of vias has at least one via configuration from among those below:
the side wall of the via is made of a dielectric material, and the via is filled with an electrically conductive or semiconductive material or the via is hollow,
the side wall of the via is made of a dielectric material, and the via is filled with the material of the first layer,
the side wall of the via is made of the material of the first layer and the via is hollow.

According to an example, the via configurations differ for at least one of the following properties: the dielectric nature, or not, of the side wall of the via; the shape of the via (and in particular, the transverse cross-section), the dimension, the filling material of the via, the hollow or solid character of the via.

According to an example, the formation of the plurality of vias comprises, for at least one assembly of vias and on at least one first portion of said vias, an etching of at least one perimeter of the via.

According to an example, the etching is configured so as to only etch the perimeter of the via. Equivalently, the etching is configured to etch a groove forming the perimeter of the via. Thus, after formation of an oxide in the groove, the side wall of the via is made of a dielectric material, and the via is filled with the material of the first layer.

According to another example, the etching is configured so as to etch the via over substantially all of its volume. Thus, the side wall of the via can be made of the material of the first layer and the via can be hollow. Alternatively, after formation of an oxide on the perimeter of the formed cavity, the side wall of the via can be made of dielectric material and the via can be hollow or filled.

According to an example, the formation of the plurality of vias comprises, following the etching at least of the perimeter of the via, a formation of a dielectric material on at least the etched perimeter of the via, so as to form the side wall of the via made of dielectric material.

According to an example, during the etching of at least the perimeter of the via, the via is etched over substantially all of its volume, and the formation of the plurality of vias comprises, following the formation of a dielectric material on at least the etched perimeter of the via, so as to form the side wall of the via made of dielectric material, a deposition of an electrically conductive or semiconductive material, so as to fill at least partially the via. Thus, the side wall of the via is made of dielectric material, and the via is filled with electrically conductive or semiconductive material.

It is therefore understood that these different steps make it possible to lead to the via configuration described above.

According to an example, the formation of the plurality of vias comprises the formation of several via assemblies, each forming a pattern repeated along at least one direction of the main extension plane of the first and second layers.

According to an example, the formation of the via assemblies is configured, such that each assembly has at least one via configuration, distinct from another assembly.

According to an example, the formation of the plurality of vias is configured such that at least one via, and preferably at least some of the plurality of vias has a first via configuration on a first portion, and a second via configuration, distinct from the first via configuration on a second portion, the first and second portions extending along a dimension in thickness of the first and second layers.

According to an example, the formation of a dielectric material at at least the bottom wall and the side wall of the plurality of vias comprises:
a thermal oxidation, so as to oxidise the semiconductive material of the first layer at at least the bottom wall and the side wall, and/or
a deposition of the dielectric material at at least the bottom wall and the side wall.

These techniques, and quite specifically, thermal oxidation, make it possible to obtain a good conformity of the dielectric material walls. With thermal oxidation being conform, it makes it possible to obtain an oxide which is both dense and of uniform thickness on the bottom and side walls. Thermal oxidation is therefore particularly advantageous in synergy with high via form factors. With respect to a deposition, thermal oxidation further enables a smoothing of the etched via wall and limits the presence of defects between the semiconductive material of the first layer and the dielectrics.

According to an example, when the side wall is made of dielectric material, the side wall of the plurality of vias has a transverse dimension substantially between 50 nm and 600 nm, preferably substantially equal to 400 nm.

According to an example, when the bottom wall is made of dielectric material, the wall has a longitudinal dimension substantially of between 50 nm and 600 nm, preferably substantially equal to 400 nm.

According to an example, the superficial layer of the donor sub-substrate is a layer with the basis, and preferably made, of a material chosen from among a dielectric material, for example, an oxide, a semiconductive material or a piezoelectric material.

According to an example:
the support sub-substrate further comprises a superficial layer with the basis, and preferably made, of a dielectric material, for example, an oxide, surmounting the first layer, the superficial layer having the exposed surface, and/or
the superficial layer of the donor sub-substrate is a layer with the basis, and preferably made, of a dielectric material, for example, an oxide, surmounting a layer based on a material chosen from among a semiconductive material or a piezoelectric material.

It is therefore understood that the buried oxide layer of the substrate can come from the donor sub-substrate and/or from the support sub-substrate.

According to an example, the superficial layer of the donor substrate is with the basis, preferably made, of one from among a semiconductive material or a dielectric material. According to which, the superficial layer is based on a semiconductive material or a dielectric material, it is understood that the upper wall of the vias, and if necessary, of the grooves, is based on made of a semiconductive material or of a dielectric material.

According to an example, the method for manufacturing the substrate further comprises, prior to the assembly of the support sub-substrate and of the donor sub-substrate, an etching of a groove fully surrounding at least one via on at least one portion of a longitudinal dimension of said via, the groove extending from the superficial layer into the first layer. The effects and advantages described relative to the groove are therefore obtained.

According to an example, the method comprises a formation of an embrittlement zone at a depth of the surface of the superficial layer of the donor substrate, then a separation of the donor substrate at the embrittlement zone.

According to an example, the method for manufacturing the microelectronic device comprises, a selection of at least one via to be etched from among the plurality of vias, only some of the plurality of vias being selected as a via to be etched. Thus, it is possible to select the vias to be etched from among the vias present in the substrate. The method can thus be adapted according to the desired microelectronic device configuration, for different microelectronic devices. This selection can be made prior to an etching by one from among the front or back exposed surfaces of the substrate.

According to an example, the selection of at least one via to be etched comprises the application, on said front or back exposed surface of the substrate, of a mask comprising openings located in vertical alignment with the at least one via to be etched, followed by the etching so as to reach the at least one via to be etched. Thus, a potential embrittling of the wall of the vias to be etched is avoided, with respect to an extended thinning of the face of the substrate. This etching thus etches the layer at the right of the at least one via to be etched until opening into the at least one via to be etched.

According to an example, when the method implements the etching by the other from among the front or back exposed surfaces of the substrate, until reaching the via, the selection of the at least one via to be etched from among the plurality of vias comprises the application, on said other front or back exposed surface of the substrate, of a mask comprising openings located in vertical alignment with the at least one via to be etched, and the method further comprises an etching so as to reach the at least one via to be etched. This is particularly advantageous when the via is filled with an electrically conductive or semiconductive material, including the material of the first layer. This makes it possible to reach the via by the back and front faces of the substrate, to provide electrical continuity to the via.

According to an example, the deposition of the electrically conductive or semiconductive member is configured so as to further cover, by an electrically conductive or semiconductive layer, at least one portion of the front and/or back exposed surface of the substrate.

According to an example, the method comprises a production of patterns in the electrically conductive or semiconductive back layer.

According to an example, the method comprises the passivation of the back exposed surface of the substrate.

According to an example, the method for manufacturing a microelectronic device comprises:
between the formation of the at least one layer portion of the device, and the etching by the back exposed surface of the substrate, the mounting of a support on the front exposed surface of the substrate, and
after the deposition of the electrically conductive or semiconductive member so as to fill the electrical cavity, the dismounting of the support.

The support thus makes it possible to facilitate the handling of the substrate.

By microelectronic device, this means any type of device produced with microelectronic means. These devices in particular include, in addition to devices with a purely electronic purpose, micromechanical or electromechanical devices, as well as optical or optoelectronic devices. This can be a device intended to ensure an electronic, optical, mechanical function, etc. This can also be an intermediate product, only intended for the production of another microelectronic device. This can also be a passive electrical interconnecting structure.

It is specified that, in the scope of the present invention, the term “on” or “above” does not compulsorily mean “in contact with”. Thus, for example, the deposition of a layer on another layer, does not compulsorily mean that the two layers are directly in contact with one another, but this means that one of the layers covers the other at least partially, either directly in contact with it, or by being separated from it by a film, also another layer or another element.

A layer can moreover be composed of several sublayers of one same material or of different materials.

By an element “based on” a material A, or A-based, this means an element comprising this material A only, or this material A and optionally other materials.

In the detailed description below, use can be made of terms such as “longitudinal”, “transverse”. These terms must be interpreted relative to the substrate or to the dimension in thickness of the devices. Thus, a longitudinal dimension, a height, a depth or a thickness of an element or of a layer means a dimension along the thickness of the substrate which carries it or contains it. A width, or also a cross-section or a transverse dimension means a dimension perpendicular to the thickness of the substrate.

Certain parts of the substrate or of the device of the invention can have an electrical function. Some are used for electrical conduction properties, and by electrically conductive or equivalent, this means, elements formed of at least one material having a sufficient conductivity, in the application, to carry out the desired function. Other parts, on the contrary, are used for electrical isolation properties and all materials having a sufficient resistivity to achieve this isolation are concerned, and are, in particular, called dielectric or electrically isolating.

The word “dielectric” qualifies more specifically a material of which the electrical conductivity is sufficiently low in the given application to serve as an insulator. In the present invention, a dielectric material preferably has a dielectric constant of less than 4.

By “direct bonding”, this means a bonding without adding adhesive material (of the glue or polymer type, in particular) which consists of the contacting of relatively smooth surfaces (of a Root Mean Square (RMS), of typically less than 5 Å, 10⁻¹⁰ m), for example, achieved at ambient temperature and under ambient atmosphere, in order to create an adherence between them.

According to an embodiment, the direct bonding of two substrates means that the bonding is obtained by chemical bonds which are established between the two contacted surfaces. These chemical bonds can be, for example, Van der Waals bonds and/or strong, covalent chemical bonds, in particular when the bonding is enhanced by a plasma activation, or followed by a reinforcing heat treatment (typically 200 to 1200° C. for 1 hour).

The direct bonding can be obtained without requiring the application of a significant pressure on the structure to be assembled. A slight pressure can simply be applied to initiate the bonding. A thermal annealing can further be carried out to reinforce the bonding.

By a parameter which is “substantially equal to/greater than/less than” a given value, this means that this parameter is equal to/greater than/less than a given value, plus or minus 10%, even plus or minus 5%, of this value.

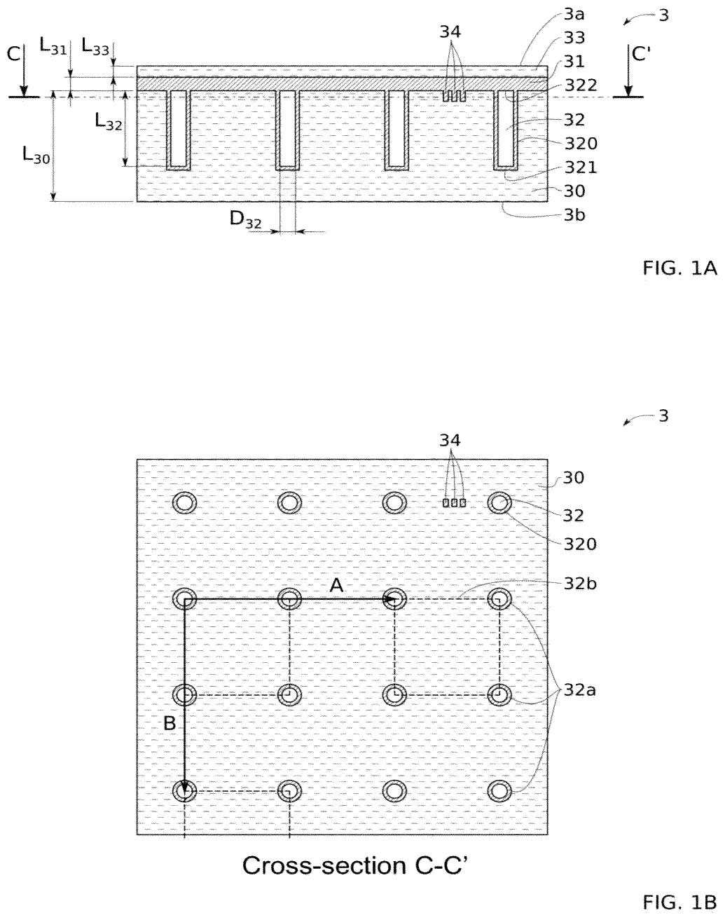

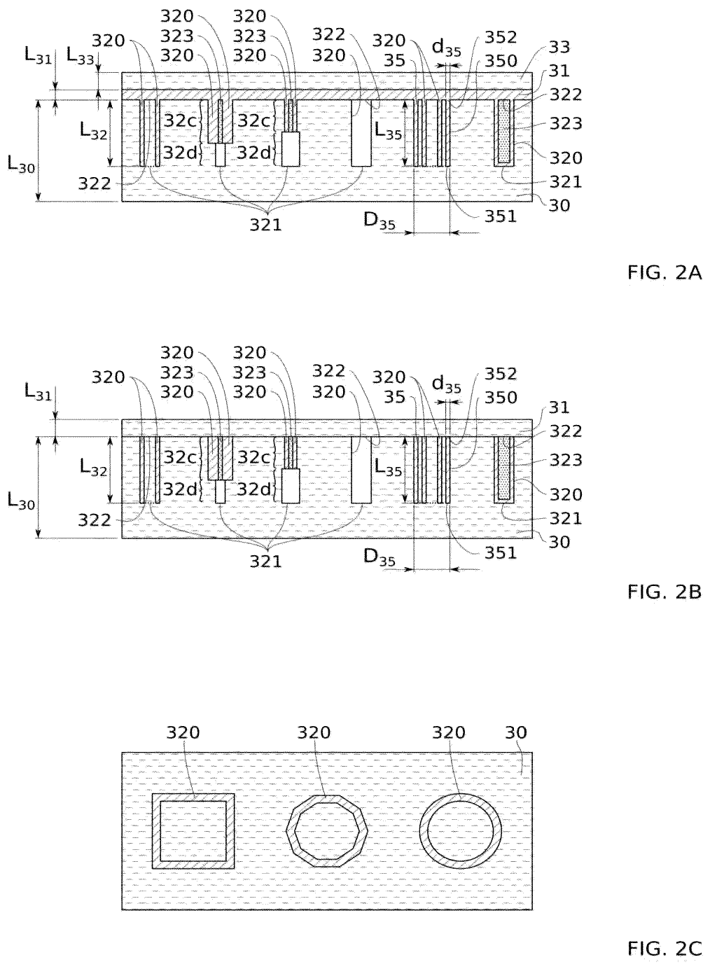

The substrate 3 is now described according to several examples of embodiments in reference to FIGS. 1A to 2C.

As, for example, illustrated by FIG. 1A, the substrate 3 comprises a first layer 30, with the basis or made of a semiconductive material. According to an example, the semiconductive material comprises, and preferably is, silicon. As described below, it is noted that other semiconductive materials can be considered. The first layer 30 has a thickness L₃₀, for example, substantially between 100 μm and 800 μm.

The substrate 3 further comprises a second layer 31. As illustrated by FIGS. 1A and 2A, the second layer 31 can be with the basis or made of a dielectric material. According to an example, the dielectric material comprises, and preferably is, a semiconductive oxide, for example, silica of formula SiO₂. The second layer 31 surmounts the first layer 30, preferably by being directly in contact with it. As illustrated by FIG. 2B, the second layer 31 can alternatively be with the basis or made of a semiconductive material, preferably monocrystalline, or of a piezoelectric material. The second layer 31 can have a thickness L₃₁, for example, greater than or equal to 10 nm, preferably 100 nm. The thickness L₃₁ can be less than or equal to 3000 nm. The second layer 31 of the substrate 3 preferably has no metal portions. The second layer 31 is preferably continuous in the main extension plane of the substrate 3.

According to an example, being able to be illustrated by FIGS. 1A and 2A, the second layer 31 is surmounted by a third layer 33 with the basis or made of a semiconductive material, preferably monocrystalline, or of a piezoelectric material. According to an example, the semiconductive material comprises, and preferably is, silicon. In this case, as described below, it is also noted that other semiconductive materials can be considered. The third layer 33 has a thickness L₃₃, for example, substantially between 10 nm and 20000 nm. The substrate 3 can therefore comprise a structure of the semiconductor-on-insulator-type, and in particular of the silicon-on-insulator (SOI)-type. It is noted that it can be provided that the second layer 31 is not surmounted by a third semiconductive layer. The third layer 33 of the substrate 3 preferably has no metal portions. The third layer 33 is preferably continuous in the main extension plane of the substrate 3.

According to an example, the material based on which a layer 30, 31, 33 is formed, is preferably continuous in the extension plane of the layer. At least one and preferably each layer(s) 30, 31 33 is preferably continuous over at least 80%, preferably over at least 90%, and even more preferably all, of the main extension plane of the substrate 3.

The first layer 30 and/or the second layer 31 is/are preferably monolithic. The first layer 30 is preferably monolithic over at least the portion over which the vias 32 extend.

Below, unless explicitly mentioned on the contrary, it is considered in a non-limiting manner, that the substrate 3 is an SOI substrate, the first layer 30 being made of monocrystalline silicon, the second layer made of SiO₂ and the third layer made of monocrystalline silicon.

The substrate 3 comprises vias 32 extending from the second layer 31 in the first layer 30. The vias 32 extend preferably over a longitudinal dimension L₃₂ oriented in the direction of the thickness of the first 30 and second 31 layers. The vias 32 can be parallel to one another. The vias 32 are buried in the substrate 3, i.e. that they do not open onto one or the other of the exposed surfaces 3a, 3b of the substrate 3. The vias 32 therefore define a closed volume.

Thus, the substrate 3 comprises vias 32 for their subsequent use in a method for manufacturing a microelectronic device. This makes it possible to provide the vias independently of the other steps of producing a microelectronic device 4, as described below in reference to the method for manufacturing the microelectronic device.

The longitudinal dimension L₃₂ can be chosen, such that the vias 32 are flush on the surface of the first layer 30, at the interface with the second layer 31, as, for example, in FIGS. 1A to 2A and 2C. In a variant, not illustrated in this case, the vias 32 can further extend over a portion of the thickness L₃₁ of the second layer 31. It is the case, for example, when the donor sub-substrate 2 and the support sub-substrate 1 each have a superficial layer based on a dielectric material, these superficial layers together forming the second layer 31 after the assembly.

With the vias 32 being non-opening, they are delimited by a side wall 320, a bottom wall 321 and an upper wall 322 opposite the bottom wall 321. It is noted that the front surface 3a and the back surface 3b of the substrate 3 can be defined interchangeably with respect to the bottom 321 and upper 322 walls of the vias. Below, and including for the method for manufacturing the microelectronic device described below, it is considered in a non-limiting manner that the bottom wall 321 is disposed towards the back surface 3b of the substrate 3 and the upper wall 322 is disposed towards the front surface 3a of the substrate 3. The methods described below can however be adapted to the case where the bottom wall 321 is disposed towards the front surface 3a of the substrate 3 and the upper wall 322 is disposed towards the back surface 3b of the substrate 3.

One and/or the other of the exposed surfaces on the substrate 3 can be based on a semiconductive material, preferably monocrystalline. The vias 32 can be surmounted by a layer or a stack of layers comprising at least one layer based on a semiconductive material, preferably monocrystalline. It is therefore understood that the second layer 31 and/or the second layer 33 can be based on a semiconductive material, preferably monocrystalline, as described above. Thus, the generic substrate 3 comprising the vias is compatible with the FEOL and BEOL steps.

For example, the selection of the vias 32′ to be etched can be done by the front face, and for example after an etching of the substrate 3 of the vias 32 on the back face. The selection of the vias 32′ to be etched can be done by the back face, and for example, before or after an etching of the substrate 3 of the vias 32 on the front face.

According to an example being able to be illustrated by FIGS. 1A and 1B, the vias 32 form at least one assembly 32a comprising a pattern 32b repeated at least once along at least one direction, preferably two directions, of the main extension plane of the first 30 and second 31 layers. These directions are preferably perpendicular. It can be provided that these directions are not perpendicular to one another. At least one via 32 pattern 32b and one or more via 32 assemblies 32a repeating a pattern 32b are therefore had. Each assembly comprises a repeated via 32 pattern 32b. The patterns 32b can be different between several assemblies 32a.

A pattern 32b can only comprise one single via 32, or several vias 32 as illustrated in FIG. 1B. The via pattern 32b can be of any shape. According to an example, several vias 32 can form a polygonal pattern taken in a plane parallel to the main extension plane of the first 30 and second 31 layers. The via 32 patterns 32b can be disposed at regular intervals in the main extension plane of the first 30 and second 31 layers.

Thus, the substrate 3 can be a generic substrate comprising a via matrix, in which vias 32 to be etched will be chosen according to the electrically conductive or semiconductive members to be formed, as described in more detail below.

For this, the via 32 patterns 32b can be successively separated by a first pitch A along a first direction contained in the main extension plane of the first 30 and second 31 layers. The via 32 patterns 32b can be successively separated by a second pitch B along a second direction contained in the main extension plane of the first 30 and second 31 layers, distinct from the first. Preferably, these first and second directions are perpendicular. These pitches are taken centre-to-centre between a via of the pattern 32b and the corresponding via of the following pattern 32b, as FIG. 1B illustrates. The pitches A and/or B are preferably constant, i.e. substantially identical for each pattern repetition.

One and/or the other of these pitches A and B can be substantially between 50 μm and 300 μm, preferably between 100 μm and 200 μm. These pitches can be different from one another or equal to one another, according to the desired matrix geometry.

According to a preferable example, the substrate 3 comprises one single via 32 pattern 32b, preferably comprising one single via 32. According to this example, each via 32 is separated from the neighbouring via(s) 32 by the pitches A and B substantially identical for each pattern repetition. The pitches A and B are preferably equal to one another.

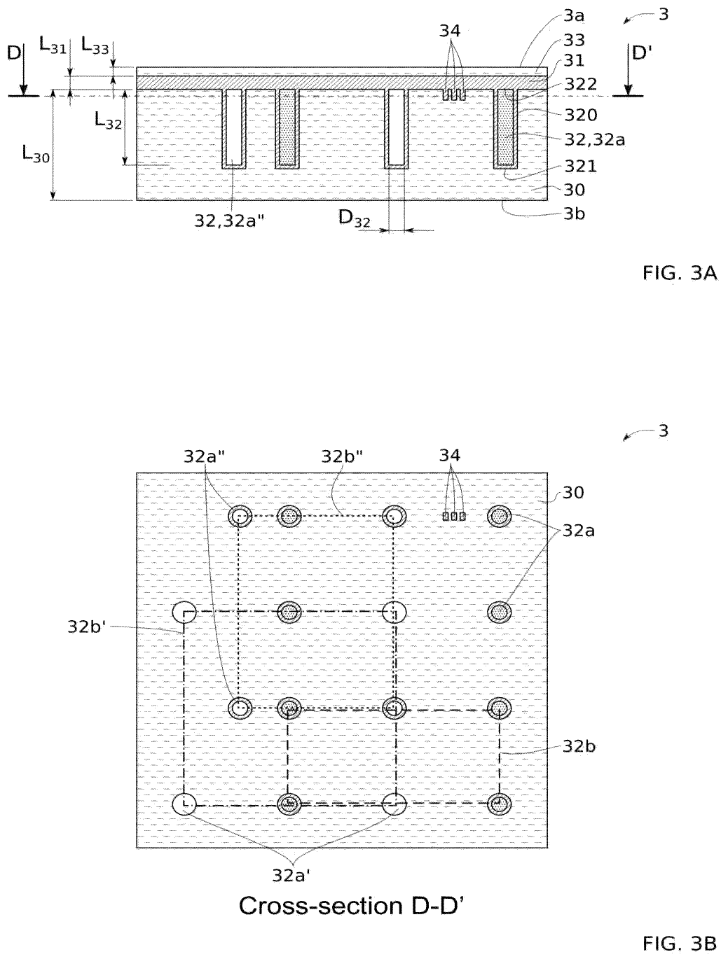

According to an example illustrated by FIGS. 3A and 3B, the vias 32 form several assemblies 32a, 32a′, 32a″, i.e. at least two assemblies or more. Each assembly 32a, 32a′, 32a″ can comprise a via pattern 32b repeated as described above. The patterns 32b, 32b′, 32b″ of different assemblies can be different, as, for example, FIG. 3B illustrates.

The pattern(s) 32b can be repeated along a direction, preferably along the two distinct directions above, of the main extension plane of the first 30 and second 31 layers, over at least 80% of the dimension of the substrate 3 along this/these direction(s). The via 32 pattern(s) 32b are preferably repeated, in the main extension plane of the first layer 30, over at least 80%, preferably at least 90%, and even more preferably at least 95%, of the main extension plane of the first layer 30. The via 32 pattern(s) 32b are further preferably repeated, in the main extension plane of the substrate 3, over at least 80%, preferably at least 90%, and even more preferably at least 95%, of the main extension plane of the substrate 3. The generic substrate 3 thus comprises one or more generic via 32 matrices over a large part of its surface, to facilitate the manufacturing a microelectronic device as described in detail below. These vias 32 can, in particular, be selected according to the desired architecture, with a generic substrate 3 which can be adapted to manufacturing different microelectronic devices.

According to an example, at least some of the vias 32 and preferably each via, extends over a height greater than or equal to 50% of the thickness of the substrate 3, preferably greater than or equal to 70% of the thickness of the substrate 3.

The vias 32 can moreover have a configuration from among several configurations, or equivalently, a structure from among several structures. For example, the vias 32 can be at least partially hollow and/or at least partially filled with a solid material. These configurations are now described in reference to FIGS. 2A to 2C, which illustrate different possible via configurations. The repeated via patterns 32b are not represented.

According to an example, the side wall 320 of the via 32 can be made of a dielectric material, and the via 32 can be filled with an electrically conductive or semiconductive material 323. This configuration is compatible with the FEOL steps.

The side wall 320 of the via 32 can be made of a dielectric material and the via 32 can be hollow. Preferably, according to these examples, at least the side wall 320 and the bottom wall 321 are made of dielectric material. The upper wall 320 can be made of dielectric material or of semiconductive material or of piezoelectric material, as will appear more clearly during the description of the method for manufacturing the substrate 3.

According to another example, the side wall 320 of the via 32 can be made of a dielectric material, and the via 32 is filled with the material of the first layer 30. According to this example, the bottom wall 321 of the via can be located at the normal of the side wall 320 at its end. This bottom wall cannot be physically materialised by a change of material, as the dotted line illustrated in FIG. 2A.

According to another example, the via 32 can be hollow and not delimited by a dielectric material side wall. The side wall 320 of the via 32 can be made of the material of the first layer 30.

When the via 32 is hollow, it is not filled with a solid material. The via 32 is preferably filled with a gaseous atmosphere such as air, nitrogen or argon, optionally at a pressure less than or equal to the ambient pressure.

When at least the bottom wall 321 and the side wall 320 are made of dielectric material, the via 32, once filled with an electrically conductive or semiconductive material, will be electrically isolated from the first layer 30 and from the other vias 32. In a variant, the walls of the vias 32, and in particular the side wall 320, can be made of a semiconductive material, and more specifically, of the same material as that of the first layer 30. The electrical isolation of the vias 32 can subsequently be achieved during the method for manufacturing the microelectronic device from the substrate 3, described below.

The vias can have a transverse dimension D₃₂, for example a diameter, substantially less than or equal to 30 μm, preferably substantially between 1 μm and 30 μm, preferably substantially between 5 μm and 15 μm, and even more preferably between 8 and 12 μm. Thus, the side dimension D₃₂ is less than the typical dimensions of TSV-lasts, which makes it possible to have a greater number of vias 32 for one same surface of the substrate 3 in the main extension plane of the first 30 and second 31 layers, i.e. a greater via 32 density. The longitudinal dimension of the vias L₃₂ can be around the thickness L₃₀ of the layer 30, the vias 32 being non-opening. L₃₂ can be substantially less than or equal to 200 μm, preferably substantially between 50 and 150 μm, for example, substantially equal to 100 μm. These length ranges make it possible to facilitate the formation of an electrically conductive or semiconductive through member, for example, a interconnection through the via 32, of the substrate 3 during the manufacturing of the microelectronic device 4.

A via 32 can further have several portions each having a configuration, the configurations being different between the portions. For example, a via can have a first portion 32c with a configuration, and a second portion 32d with a different configuration, as illustrated, for example, in FIGS. 2A and 2B. The side dimension D₃₂ of a via can be different between the portions, for example, the first portion 32c and the second portion 32d. In particular, a first portion can be filled and a second portion can be hollow. This makes it possible to obtain a via of smaller dimension, while facilitating access by the hollow portion.

The vias 32 can have a form factor substantially greater than or equal to 5, and preferably greater than or equal to 10. By form factor, this means the ratio between the longest dimension over the shorter dimension. In this case, the form factor F is such that F=L₃₂/D₃₂. This form factor makes it possible to facilitate the formation of an electrically conductive or semiconductive through member, for example, a through interconnection by the via 32, during the manufacturing of the device, and to increase the via 32 density on the substrate.

As illustrated in FIG. 2C, a via can have a transverse cross-section, for example, in a plane substantially parallel to the main extension plane of the first 30 and second 31 layers, square-, polygonal-, or cylindrical-shaped. Preferably, the vias 32 are cylindrical.

According to an example illustrated in FIGS. 2A and 2B, a via 32 can comprise a groove 35 configured to improve the electrical isolation of the vias 32. The substrate 32 is thus particularly adapted for high-frequency applications and/or in replacement of the substrate with high resistivity for applications demanding it. For this, the via 32 has a transverse cross-section fully surrounded by the groove 35, taken in the main extension plane of the first 30 and second 31 layers. The groove 35 can surround the via 32 over at least one portion of its longitudinal dimension L₃₂. The grooves 35 are preferably disposed so as to isolate the vias 32 from one another, a groove 35 preferably surrounding one single via 32. The grooves 35 preferably do not touch one another. The groove 35 can more specifically extend from the second layer 31 over a portion of the first layer 30. It is noted that the groove 35 can be disposed around a via 32, whatever its configuration described above. The groove gives a better dielectric isolation to the via configuration that it surrounds.

Each groove 35 is preferably buried, i.e. that it does not open onto one or the other of the exposed surfaces 3a, 3b of the substrate 3. Each groove 35 therefore defines a closed volume. Each groove 35 can be hollow, it is not filled with a solid material. Each groove 35 is thus preferably filled with a gaseous atmosphere such as air, nitrogen or argon, optionally at a pressure less than or equal to the ambient pressure. Each groove 35 can be filled, preferably fully, with a solid material, and for example, with a dielectric material.

Each groove 35 can be delimited by a side wall 350, a bottom wall 351 and an upper wall 352 opposite the bottom wall 351. The bottom wall 351 is disposed towards the back surface 3b of the substrate and the upper wall 352 is disposed towards the front surface 3a of the substrate 3. From among these walls, at least the bottom wall 351 and the side wall 350 can be made of dielectric material, for example, made of SiO₂. As FIG. 2A illustrates, all the walls can be made of dielectric material. It can be provided that the groove 35 is flush with the surface of the first layer 30, like the vias 32 illustrated in FIGS. 2A and 2B. The upper wall 352 can be of the same material as the second layer 31. All the walls can be made of the same material as the layer in which or against which they extend, made of dielectric, semiconductive or piezoelectric material along the layer considered.

As illustrated, for example, by FIGS. 2A and 2B, each groove 35 can have a longitudinal dimension, or equivalently, a depth, L₃₅ substantially equal to or less than that of the via L₃₂, according to an example, equal to plus or minus 5 μm.

As illustrated, for example, by FIGS. 2A and 2B, each groove 35 can have a transverse dimension D₃₅ taken on either side of the via 32, for example, a diameter, substantially less than or equal to 50 μm, preferably substantially between 20 μm and 30 μm. Each groove 35 can have a width substantially less than or equal to 5 μm, for example, substantially between 2 and 4 μm. Thus, similarly to the dimensions of the vias 32, an improvement of the electrical isolation can be obtained, while making it possible to obtain a large via 32 density. Synergistically, it is particularly advantageous to use these grooves 35 when the vias 32 are close to one another, as is the case for a high via 32 density on the substrate 3, in order to improve their electrical isolation. By high density, for example, the pitches A and/or B are less than or equal to 100 μm. It can be provided that the grooves 35 have equal or distinct dimensions between the different grooves 35.

Along the dimensions of the grooves 35 in the main extension plane of the first 30 and second 31 layers, the pitch can be adapted, such that the grooves 35 are distinct from one another. Each groove 35 can be cylindrical, and preferably concentric to the via 32 that it surrounds.

When the substrate 3 comprises several assemblies 32a, each assembly can have a via configuration, or if necessary, several configuration sections. The via configurations 32 of different assemblies 32a can differ from one another. Preferably, each via 32 of one same assembly 32a has the same via configuration, or if necessary, several configuration sections. The dimensions of the vias 32 can further vary between the different assemblies 32a. Preferably, each via 32 of one same assembly 32a has the same dimensions. The transverse cross-section of the vias 32 can further vary between the different assemblies 32a. Preferably, each via 32 of one same assembly 32a has the same transverse cross-section.

For example, as FIGS. 1A, 1B, and 3A, 3B illustrate, the substrate 3 can comprise at least one mark, or equivalently, a marker 34 enabling the alignment of the substrate 3 with other elements. Thus, the placement of the vias 32 during the method for manufacturing the microelectronic device is made more reliable. This marker 34 can be formed by one or more dielectric material layer portion(s) at the first layer 30 and/or of the second layer 31. It is noted that a person skilled in the art can absolutely consider other variants of markers, like for example, a marking disposed on the front surface 3a or the back surface 3b of the substrate 3.

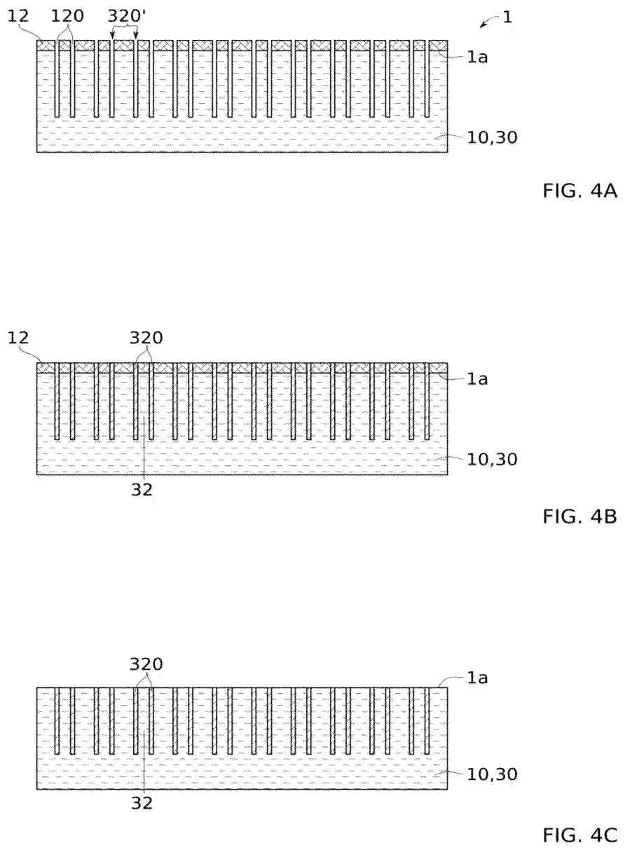

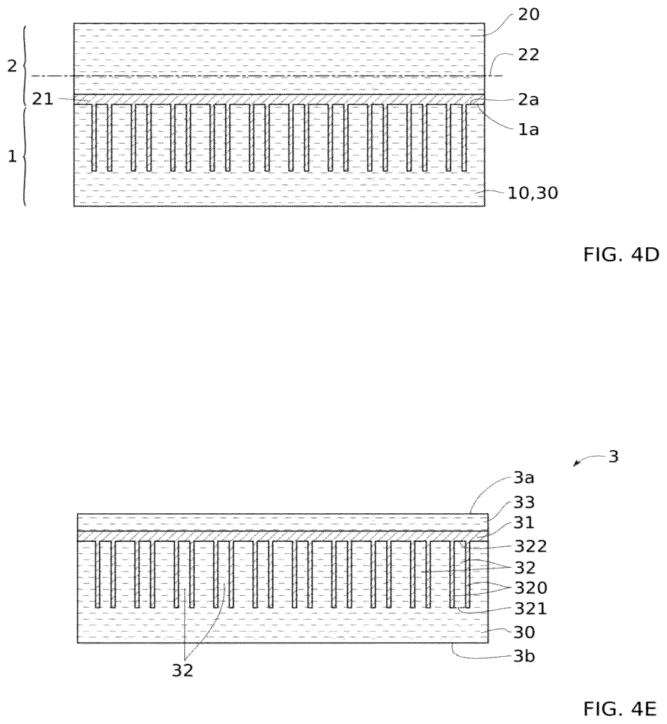

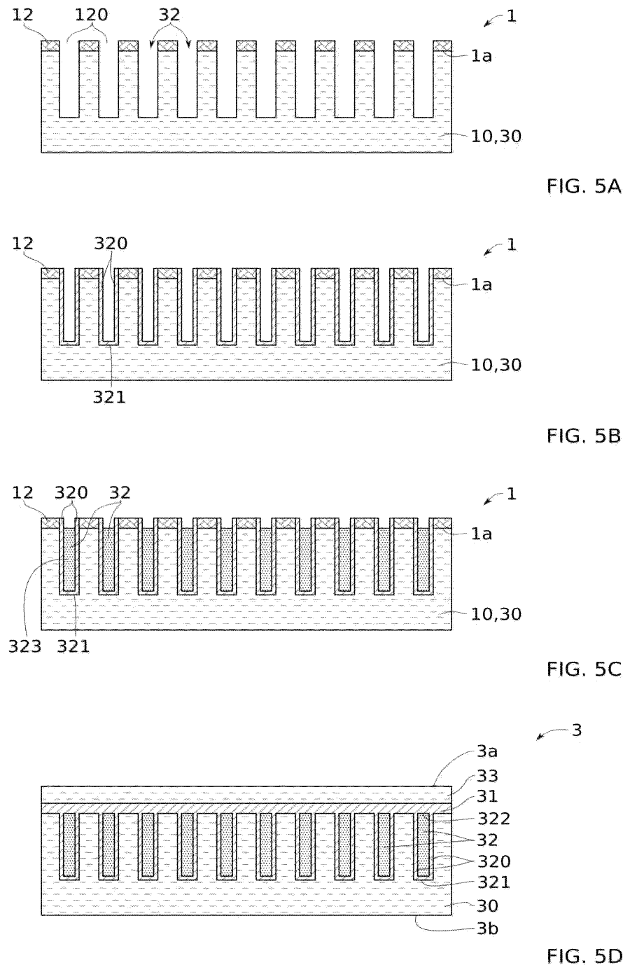

The method for manufacturing the substrate 3 is now described in reference to FIGS. 4A to 5D.

The method comprises the provision of a sub-substrate 1. The sub-substrate 1 comprises at least one first layer 10, intended to form the first layer 30 of the substrate 3 which will be obtained, as, for example, FIGS. 4A and 5A illustrate. According to an example not illustrated, the sub-substrate 1 can further comprise a superficial layer intended to form at least partially the second layer 31 of the substrate 3. The superficial layer is preferably with the basis or made of a dielectric material. The sub-substrate 1 further has an exposed surface 1a, at the first layer 10 or at the superficial layer 11.

For example, as illustrated by FIGS. 4A and 5A, the vias 32 can be formed by etching, and preferably by deep reactive ion etching (DRIE). For this, the etching step can comprise the application of a mask 12 comprising openings 120 from which the vias 32 will be etched, as, for example, FIG. 5A illustrates. The mask 12 is preferably a resin mask. It can be provided that the mask is hard, for example, with the application of a resin mask 12, then the etching of the dielectric material superficial layer 11, removing this mask and etching the first layer 10 thanks to the so-called “hard” oxide mask thus formed. It is noted that the superficial layer 11 can be removed after the etching of the vias 32, and the vias 32 electrically isolated by the subsequent deposition of a dielectric layer.

The etching is preferably configured to obtain the features of the vias 32 described above, and in particular, their dimensions and the pitches separating them. For example, the dimensions of the mask 12 and/or the etching time and etching speed are adjusted for this.

The etching is configured to only etch the perimeter of the vias 32. For example, as FIG. 4A illustrates, a groove 320′ can be etched, this groove 320′ being intended to form the side wall 320 of the via 32. In a variant, as, for example, FIG. 5A illustrates, the via 32 can be etched over substantially its entire volume.

To form the dielectric material side wall 320, the method can then comprise a formation of a dielectric material to form the side wall 320. For example, as FIG. 4B illustrates, the groove 320′ can be filled, preferably fully, with a dielectric material. For this, the dielectric material, for example, silica SiO₂, can be deposited. This deposition can be a chemical vapour deposition (CVD) from gaseous precursors comprising oxygen and silicon, for example, tetraethyl orthosilicate (TEOS) or silane of chemical formula SiH₄, optionally combined with dioxygen. The deposition is, for example, a sub-atmospheric CVD (SACVD), or a plasma-enhanced chemical vapour deposition (PECVD).

When the via 32 is etched over substantially its entire volume, the formation of the dielectric material can be done on the side wall 320 and the bottom wall 321, as, for example, FIG. 5B illustrates. This formation can be done by deposition of dielectric material as described above. This formation can, in a variant, be done by thermal oxidation, for example, at a temperature of substantially 1050° C. in an atmosphere comprising oxygen.

Preferably, the formation of the walls 320, 321 is configured such that the dielectric material walls 320, 321 have a dimension substantially between 50 nm and 600 nm, and preferably substantially equal to 400 nm. For the side wall 320, this dimension is the transverse dimension. For the bottom wall 321, this dimension is the longitudinal dimension. For example, the thermal oxidation time or the deposition time and/or deposition speed can be adjusted for this.

When the via 32 is etched over substantially its entire volume, and preferably following the formation of the dielectric material walls 320, 321, the via 32 can be filled with an electrically conductive or semiconductive material 323, like for example, illustrated in FIG. 5C. The conductive material can be a metal, for example, copper or tungsten. The semiconductive material can be polycrystalline silicon (generally called Poly-Si). This filling is preferably done by deposition of the material 323 in the via 32. For example, the deposition of Poly-Si is generally done by LPCVD (low pressure chemical vapour deposition).

According to the steps of forming vias described above, the different via 32 configurations described above can be obtained. For example, FIG. 5A can be passed from, to the assembly with the donor sub-substrate 2 to obtain hollow vias 32 without a dielectric material side wall 320. For example, FIG. 5B can be passed from, to the assembly with the donor sub-substrate 2 to obtain hollow vias 32 with the dielectric material side 320 and bottom 321.

To obtain a via with several portions, each having a configuration, it is possible to make an etching and deposition combination, even substrate layer 1 transfer to block the via in the back part of the substrate.

The mask 12 can be removed following the formation of the dielectric material, even following the filling of the via 32 with the material 323. In a variant, the mask 12 can be removed prior to the formation of these dielectric material walls. In the case where the layer 11 has served as a hard mask, it is preferable to also remove it.

The method can comprise, together with or following the formation of the vias, a step of forming the marker 34. For this, the mask can further comprise openings, not represented in this case, to etch, for example, openings in the second layer 31 until in the first layer 30. The openings can be filled with dielectric material during the formation of the walls. The formation of the marker 34 can be distinct from these steps, by the application, for example, of a mask specific to this marker 34, etching and filling of the openings. If the formation of the marker 34 is distinct from these steps, it is advantageously done before, to serve as a marker to the positioning of the vias 32.

The formation of the grooves 35 can comprise the same steps as for the etching of the vias 32, and if necessary, for the formation of the dielectric material walls. The grooves 35 can be formed simultaneously to the vias 32, the mask 12 thus comprising openings corresponding to the grooves 35 to be etched. The grooves 35 can alternatively be etched before or after the etching of the vias 32, for example, by application of a mask and an etching specific to the grooves 35. According to an example, once the grooves 35 and vias 32 are etched, a dielectric material can be formed at the walls 350, 351, 320, 321 as described above. Alternatively, the grooves 35 can be formed after the formation of the dielectric material at the walls 320 and 321. It can be provided that another formation of dielectric material is done at the walls 350, 351, according to the methods described above. The etching of the grooves 35 can otherwise not be followed by a formation of dielectric material at the walls 350 and 351. The grooves 35 and the vias 32 cannot have a dielectric material wall, according to a variant.

Following the formation of the vias 32, and if necessary, of the grooves 35, these structures can be covered to be buried during the assembly of the sub-substrate 1 with a donor sub-substrate 2. The method can therefore comprise the provision of a donor sub-substrate 2 having an exposed surface 2a′. The assembly methods described below can apply to all the examples described above.

As, for example, illustrated by FIG. 4D, the support 1 and donor 2 sub-substrates can be assembled by the contacting by direct bonding of their respective surfaces 1a, 2a. The donor substrate 2 can then be thinned, for example, by cleaving by the method known as Smart-Cut®.

The assembly can, for this, comprise, before the contacting of the surfaces 1a, 2a, the formation of an embrittlement zone 22 at a non-zero depth from the surface 2a of the donor sub-substrate 2. This embrittlement zone 22 is, for example, formed by ion implantation, such as hydrogen and/or helium ions. It is noted that any other technique of forming an embrittlement zone, and in particular, any other technique used in the SOI-type stack development methods, can be considered.

Following the assembly of the support sub-substrate 1 and of the donor sub-substrate 2, the method can comprise the separation of a superficial layer from the donor sub-substrate 2, at the embrittlement zone 22, as the passage from FIG. 4D to FIG. 4E illustrates. This separation can be done thermally or mechanically, according to steps known to a person skilled in the art.

Following the separation, the surface 3a obtained can be irregular. A polishing, chemical smoothing or chemical and/or mechanical and/or thermal curing, or atom cluster-based or monomer-based ion beam curing of the surface 3a can be done, such that the surface 3a has a crystalline quality and a roughness which is adapted for other subsequent methods. Any chemical mechanical polishing (CMP) or thermal polishing method intended to smooth a semiconductor-based, and in particular, silicon-based surface can be considered.

According to an example, the donor sub-substrate 2 comprises a layer 20 with the basis or made of a semiconductive material, for example, made of silicon and more specifically, made of monocrystalline silicon, or of a piezoelectric material. The donor sub-substrate 2 can further comprise a layer 21 with the basis or made of a dielectric material, for example, made of silica SiO₂.

According to an example, the layer 21 based on a dielectric material can form the superficial layer of the donor sub-substrate 2. A direct bonding of dielectric material can, in particular, be done, for example, silicon oxide, against a dielectric material, for example, silicon oxide. Following their assembly, the layer 21 and the layer 11 will form the second layer 31 of the substrate 3. Their respective thicknesses can therefore be chosen to obtain the desired thickness L₃₁. According to this example, it is understood that the upper wall 322 of the vias 32 and, if necessary, the upper wall 352 of the grooves 35 can be formed of a dielectric material.

In a variant, in particular, a direct bonding of dielectric material can be done, for example, silicon oxide, against the semiconductor of the layer 10 of the support sub-substrate 1. Following their assembly, the layer 21 will form the second layer 31 of the substrate 3. According to this example, it is understood that the upper wall 322 of the vias 32, and if necessary, the upper wall 352 of the grooves 35 can be formed of a dielectric material.

According to an example, the layer 20 can form the superficial layer of the donor sub-substrate 2. A direct bonding of dielectric material can be done, for example, silicon oxide, against semiconductor or piezoelectric material. Following their assembly, the layer 20 will form the second layer 31 of the substrate 3, and an intermediate dielectric layer is disposed between the first layer 30 and the second layer 31. According to this example, it is understood that the upper wall 322 of the vias 32, and if necessary, the upper wall 352 of the grooves 35 can be formed of a semiconductive or piezoelectric material.

According to an example, the layer 20 can form the superficial layer of the donor sub-substrate 2. A direct bonding of semiconductor or piezoelectric against semiconductor, and in particular silicon can be done, when the layer 20 is based on a semiconductive or piezoelectric material. Following their assembly, the layer 20 will form the second layer 31 of the substrate 3.

It is noted that it is preferable to have, for the assembly, a dielectric material thickness, and in particular, oxide thickness, of at least 10 nm at the bonding interface to avoid the appearance of defects.

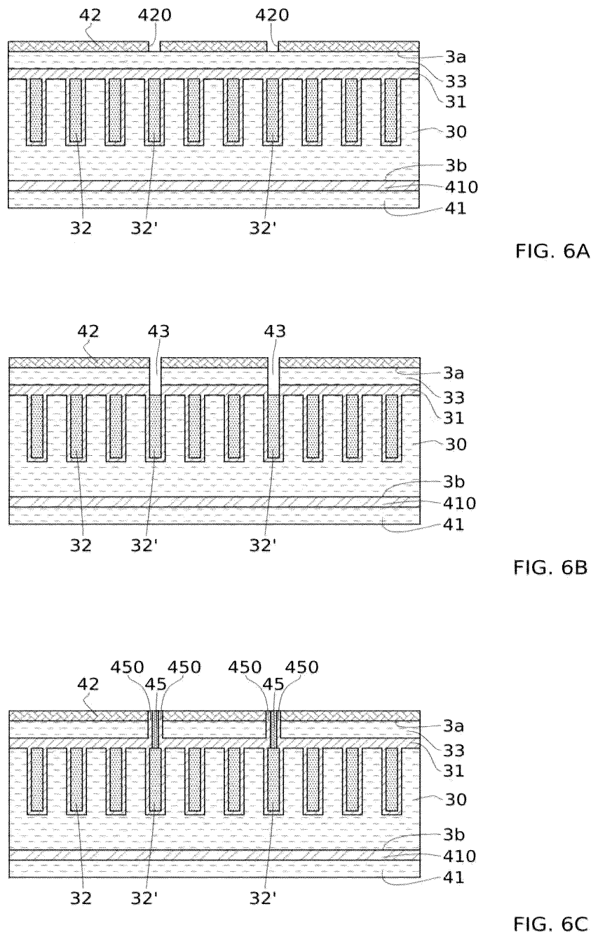

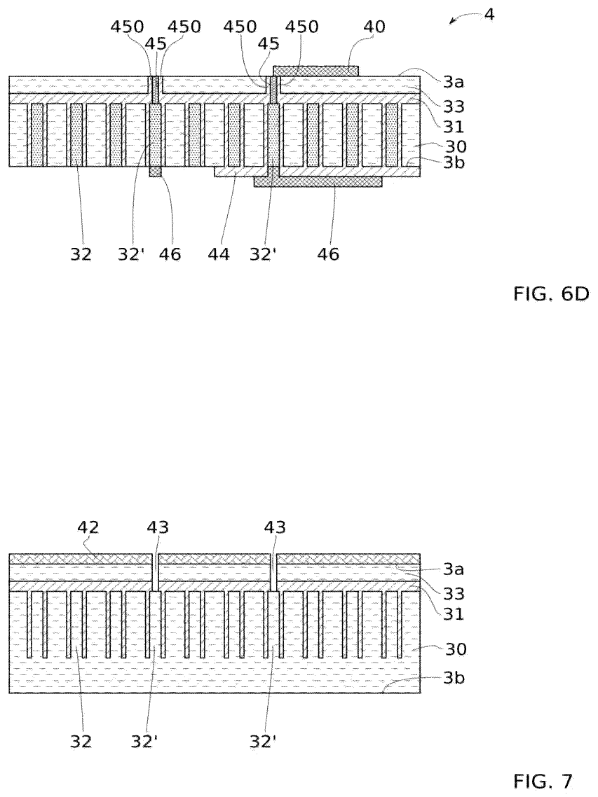

The method for manufacturing a microelectronic device 4 is now described in reference to FIGS. 6A to 8D.

In this method, the vias 32 can serve to establish interconnections. The vias 32 can alternatively or complementarily serve to form portions of a microelectronic device without necessarily being metal interconnections, for example, in a MEMS device.

The method can comprise a provision of the substrate 3. The method can comprise the deposition of layers of components, for example, transistors, diodes, memory points. This deposition can, for example, comprise FEOL steps.

As, for example, illustrated in FIG. 6D, the method can comprise the deposition of at least one layer portion 40, also called device portion 40, on the front surface 3a of the substrate 3. Below, it is considered, in a non-limiting manner, that several portions 40 are deposited. Alternatively or complementarily, the device portion(s) can be etched in the front exposed surface 3a of the substrate 3.

These portions can be metal 40 and can, in particular, form metal interconnecting lines. Typically, these metal portions 40 can serve to redistribute electrical signals. These metal portions can also be called metallisation levels. There can be several metal portions 40 with interconnections between these portions. This deposition can, for example, comprise BEOL steps.

Below, it is considered, in a non-limiting manner, that these portions 40 are metal and that the etched via 32 serves to establish an interconnection. The following steps absolutely apply to the case where non-metal device 4 portions 40 are deposited and/or etched.

The deposition of at least one layer portion 40 can be done after the formation of the vias 32 as illustrated, and if necessary, after the formation of the conductive or semiconductive members 45, or before.

In order to facilitate the handling of the substrate 3, the method can comprise the mounting of a support 41 on the side of the front surface 3a and/or of the exposed back surface 3a of the substrate 3, according to the manufacturing steps. This mounting can be done, for example, through a bonding 410, as illustrated by FIG. 6B. This further makes it possible to protect the depositions done on the surface of the substrate 3. The method can further comprise the dismounting of this support 41, for example, when it is necessary to access the surface covered by the support 41 or at the end of the method.

The method comprises the etching of at least one via 32, in order to achieve at least one provision of electrical continuity between a portion 40, the via 32 and the back surface 3b of the substrate. For this, several examples are possible and are now described. To simplify the figures, the portions 40 are not represented in all the figures. Below, it is considered, in a non-limiting manner, that several vias 32 are etched.

Preferably, the method comprises a selection of only some of the vias 32, to define a group of vias 32′ to be etched. Thus, from the generic substrate 3, only the vias of interest can be used for manufacturing the microelectronic device 4. Below, it is considered, in a non-limiting manner, that the method comprises this selection and that only some of the vias 32 are used, and not all of them.

According to a first example, as illustrated by FIG. 6A to 6D, from the front surface 3a, a cavity 43 can be created to reach the vias 32′. For this, a mask 42 can be applied on the front surface of the substrate 3. The mask can comprise openings 420 or be etched to have the openings 420. The mask can be a hard mask, for example, with the basis or made of SiO₂. The mask is, for example, deposited by PECVD.

Cavities 43 can be etched so as to reach the vias 32′, and more specifically so as to reach and preferably exceed their upper wall 322, as, for example, illustrated by FIG. 6A. For this, an SF₆ silicon etching is, for example, done. Preferably, the etching does not update the conductive material of the via 32′ at this time, in order to avoid a contamination of the substrate. This could indeed be damaging, if active devices are then produced. In order to update the conductive material 323 of the via, the method can comprise an RIE (reactive ion etching) to open the bottom of the cavity, also called “etch back”. It is preferable that the electrically conductive material of the via is only discovered after the formation of the dielectric walls 450, described below.

Once the cavities 43 are formed, the method can comprise the deposition of an electrically conductive or semiconductive member 45. This member 45 can be with the basis or made of a metal material 45, for example, electrolytic copper or CVD tungsten. Alternatively, this member 45 can be with the basis or made of a semiconductive material, for example, poly-Si. The deposition can be configured so as to fill these cavities 43 with metal material to form an electrical interconnection or a device portion 40, as, for example, illustrated by FIG. 6D.

From the back surface 3b of the substrate 3, the first layer 30 can be etched until being flush, or exceeding the bottom wall 321 of the vias 32. For this, the first layer 30 can be thinned and etched by an etching of the material of the first layer 30. All of the back surface 3b of the substrate 3 can be etched. All the vias 32 will thus be reached.

This etching can, according to an example, be a selective etching of the material of the layer 30 with respect to the dielectric material of the walls of the via 32. The etching can, for example, be a selective etching of the silicon with respect to the silica SiO₂ in reactive ion etching using a precursor such as SF₆. By “selective etching of a material A with respect to a material B”, this means that the etching speed of the material A is 10, and preferably 100 times greater than that of the material B. The carrying out of a partial mechanical thinning of the substrate 3 ended with a plasma or selective chemical etching can be considered. The dielectric material wall can then be etched selectively with respect to the material of the first layer 30, to open into the via 32′. Some vias 32′ only can be subjected to this selective etching. For example, the etching of the dielectric material can be a reactive ion etching. The etching of the semiconductive material can be similar to that done to etch the layer 30.

Alternatively or complementarily, a localised etching from the back surface 3b through a mask having openings in vertical alignment with the vias 32′ to be etched can also be considered, and the filling of the cavities etched by an electrically conductive or semiconductive member.

Preferably, prior to the deposition of the electrically conductive or semiconductive member on the front surface 3a and/or back surface 3b of the substrate 3, the method comprises the formation of the dielectric material wall 450, so as to isolate this member from the layers that it passes through, as FIG. 6C illustrates, for example. The walls 450 can be formed by a PECVD, for example, of SiO₂. This deposition is preferably sufficiently conform to cover the flanks of the cavity 43. This makes it possible to avoid a short-circuit by the substrate 3.

The method can then comprise a deposition configured so as to cover by a metal or semiconductive layer 46, at least one portion of the back exposed surface 3b of the substrate 3, to provide continuity to the device portion 40, the via 32 and the back face 3b of the substrate 3, as illustrated, for example, by FIG. 6D.

The method can further comprise at least one from among, preferably between the formation of the cavities 43 and the deposition of the layer 46:
the removal of the mask 42,
a passivation of the exposed back surface 3b of the substrate 3, for example, by formation of a dielectric material layer 44, also called passivation layer 44. This formation can be done by deposition of a dielectric material, for example, as described above,
an etching of the layer 44, so as to remove an optional oxide layer which would be formed at the via 32′. This optional oxide layer can indeed limit the electrical recontacting on the portion 40.

According to the example illustrated by FIG. 7, this method can also apply to a via having a dielectric material side wall and filled with the same material as the first layer 30. The same steps as described above can apply.

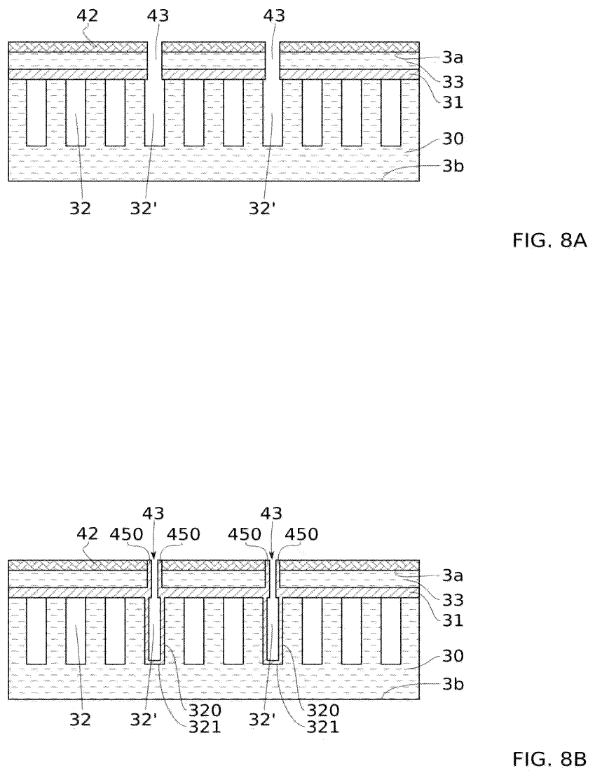

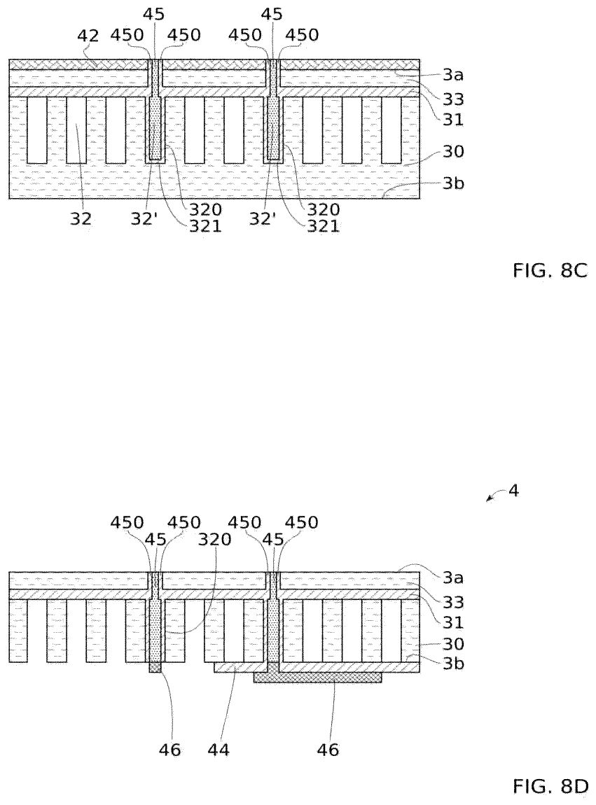

FIGS. 8A to 8D describe another example in which the vias 32 are hollow. As described above, a cavity 43 can be formed in vertical alignment with the vias 32′ to be etched, so as to open into the via 32.

When the walls of the vias 32′ to be etched are not made of dielectric material, the method can comprise the formation of a dielectric layer at at least the side wall 320, according to the methods described above in reference to the method for manufacturing the substrate 3. This example can be illustrated by FIG. 8B. Dielectric material walls 450 are further advantageously formed at the etched cavities 43.

The vias 32′ can then be filled with the electrically conductive or semiconductive member 45. The steps then described in reference to the preceding examples can apply.

In a variant, the etching can be done from a face of the substrate 3 until opening into the via 32′, and continued to form at least one cavity 43, for example, an electrical connecting cavity 43 and to reach the other face of the substrate 3, whether from the front face or the back face. The method can further comprise the other steps described above to obtain the device illustrated in FIG. 8D.

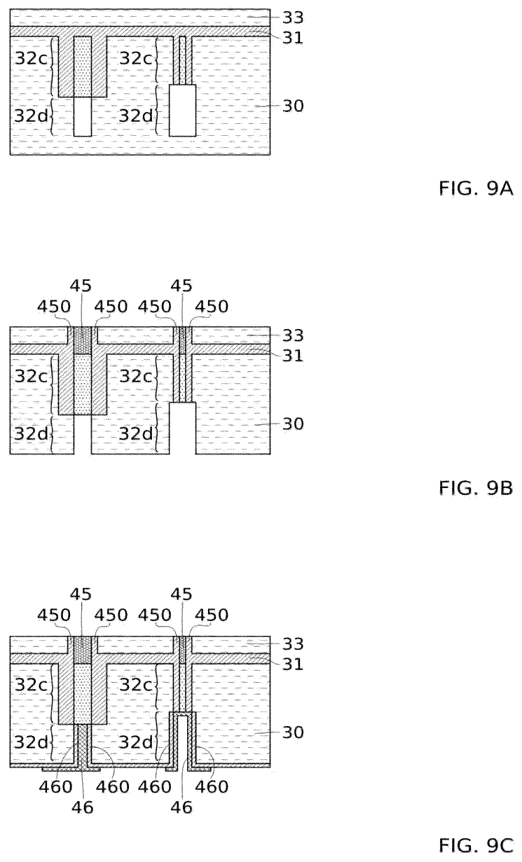

As illustrated by FIGS. 9A to 9C, the examples described can also apply to the example according to which the vias 32 have several configuration sections along one same via 32. For example, a portion filled with an electrically conductive or semiconductive material can be connected by the member 45. A hollow portion of the via 32 can be at least partially filled by the layer 46 and/or another member 45, after formation of a dielectric material wall, so as to isolate the via 32.

The examples described can also apply to the example according to which the vias 32 comprise grooves 35. In order to not fill the grooves of the conductive or semiconductive member, the openings 420 of the mask 42 can be disposed so as to not enable the etching of the grooves 35. During steps subsequent to the formation of cavities 43, the grooves 35 preferably remain closed and are not therefore filled by the member 45.

In view of the description above, it clearly appears that the invention proposes a substrate, its manufacturing method and a method for manufacturing a microelectronic device making it possible to facilitate the manufacturing of vias in a microelectronic device.

The invention is not limited to the embodiments described above and extends to all the embodiments covered by the invention. The present invention is not limited to the examples described above. Many other variants of embodiments are possible, for example, by combining features described above, without moving away from the scope of the invention. Furthermore, the features described relating to an aspect of the invention can be combined with another aspect of the invention.

In particular, the substrate can have any feature resulting from its manufacturing method and vice versa, this method can comprise any step configured to obtain a feature of the substrate. The method for manufacturing a microelectronic device can implement any feature of the substrate.

In the examples described, the semiconductive material is silicon. It is noted that the invention can absolutely apply to other mono- or polycrystalline semiconductors, optionally doped, and in particular, to Si, Ge, SiGe, SiC, III-V material (for example, AlN, GaN, InN, InGaAs, GaP, InP, InAs, AsGa, etc.), and II-VI material semiconductors. The dielectric material can be an oxide or a semiconductive nitride, for example, SiO₂, SiN, Al₂O₃. The piezoelectric material can, as an example, be chosen from among lithium tantalate (LiTaO₃), lithium niobate (LiNbO₃), potassium sodium niobate (KₓNa₁₋ₓNbO₃ or KNN), barium titanate (BaTiO₃), quartz, lead zirconate titanate (PZT), a lead magnesium and lead titanate niobate compound (PMN-PT), zinc oxide (ZnO), aluminium nitride (AlN) or aluminium scandium nitride (AlScN), other materials naturally being able to be considered.

1.-20. (canceled)

21. A substrate, comprising:
a first layer based on a semiconductive material;
a second layer surmounting the first layer; and
a plurality of buried vias extending from the second layer over a portion of the first layer, each via of the plurality of buried vias being delimited by a side wall, a bottom wall, and an upper wall opposite the bottom wall,
wherein at least one assembly of the plurality of vias forms a pattern repeated along at least one direction of a main extension plane of the first layer and the second layer.

22. The substrate according to claim 21, wherein said each via of the plurality of buried vias has at least one transverse dimension of between 1 μm and 30 μm.

23. The substrate according to claim 21, wherein at least some of the vias has an aspect ratio greater than or equal to 10, of longest dimensions oriented along a dimension in thickness of the first layer and the second layer.

24. The substrate according to claim 21, wherein, within a via assembly, two via patterns repeated successively are separated by a constant pitch along at least one direction of the main extension plane of the first layer and the second layer, the pitch being between 50 μm and 300 μm.

25. The substrate according to claim 21, further comprising one single via assembly forming a pattern comprising one single via, each via being separated from the closest neighbouring vias by a constant pitch, along two directions distinct from the main extension plane of the first layer and the second layer.

26. The substrate according to claim 21, further comprising several via assemblies, each forming a pattern repeated along at least one direction of the main extension plane of the first layer and the second layer.

27. The substrate according to claim 21, wherein at least one via of the plurality of buried vias has at least one via configuration from among the following:
the side wall of the via being made of a dielectric material, and the via being filled with an electrically or semiconductive material or the via being hollow,
the side wall of the via being made of a dielectric material, and the via being filled with the material of the first layer,
the side wall of the via being made of the material of the first layer and the via being hollow.

28. The substrate according to claim 27, wherein at least one via has a first via configuration on a first portion, and a second via configuration distinct from the first via configuration on a second portion, the first portion and the second portion extending successively along a dimension in thickness of the first layer and the second layer.

29. The substrate according to claim 27,
further comprising several via assemblies, each forming a pattern repeated along at least one direction of the main extension plane of the first layer and the second layer,
wherein at least one assembly has at least one via configuration distinct from another assembly.

30. The substrate according to claim 21, wherein the pattern of the at least one assembly is repeated along at least one direction of the main extension plane of the first layer and the second layer, over at least 80% of a dimension of the substrate along the at least one direction.

31. A method for manufacturing a substrate according to claim 21, the method comprising:
providing a support sub-substrate comprising at least one first layer based on a semiconductive material, the support sub-substrate having an exposed surface;
forming a plurality of vias such that the vias extend from the exposed surface over a portion of the first layer, each via being delimited by a side wall and a bottom wall, at least one via assembly forming a pattern repeated along at least one direction of a main extension plane of the first layer and the second layer;
providing a donor sub-substrate comprising a superficial layer having an exposed surface; and
assembling of the support sub-substrate and of the donor sub-substrate by their exposed surfaces, so as to cover the vias, each via thus being delimited by the side wall, the bottom wall, and an upper wall opposite the bottom wall.

32. The method according to claim 31, wherein the forming the plurality of vias comprises, for at least one via assembly, and on at least one first portion of the vias, etching of at least one perimeter of the via.

33. The method according to claim 32, wherein the forming the plurality of vias further comprises, following the etching at least of the perimeter of the via, forming a dielectric material over at least the etched perimeter of the via, so as to form the side wall of the dielectric material via.

34. The method according to claim 33, wherein during the etching of at least the perimeter of the via, the via is etched over substantially an entire volume thereof, and the forming the plurality of vias further comprises, following the forming of the dielectric material over at least the etched perimeter of the via, so as to form the side wall of the dielectric material via, deposition of an electrically conductive or semiconductive material, so as to fill the via at least partially.

35. The method according to claim 31, the forming the plurality of vias comprises forming several via assemblies, each forming a pattern repeated along at least one direction of the main extension plane of the first layer and second layer.

36. A method for manufacturing a microelectronic device, the method comprising:
providing a substrate according to claim 21, the substrate having a front exposed surface and a back exposed surface;
forming at least one layer portion of the microelectronic device by a deposition, on at least one from among the front or the back exposed surfaces of the substrate, of the at least one layer portion, and/or an etching of at least one from among the front or the back exposed surfaces of the substrate, configured so as to form the at least one layer portion;
at at least one via, an etching by one from among the front or the back exposed surfaces of the substrate, until reaching the via, and:
continuing the etching to reach the at least one layer portion of the microelectronic device, or
at the at least one via, an etching by the other from among the front or the back exposed surfaces of the substrate, until reaching the via; and
depositing at least one electrically conductive or semiconductive member, so as to provide electrical continuity to at least the via and the at least one layer portion.

37. The method according to claim 36, further comprising selecting at least one via to be etched from among the plurality of vias, only some of the plurality of vias being selected as the via to be etched.

38. The method according to claim 37, wherein the selecting the at least one via to be etched comprises applying, on the front or the back exposed surface of the substrate, a mask comprising openings located in vertical alignment with the at least one via to be etched, followed by the etching, so as to reach the at least one via to be etched.

39. The method according to claim 37, wherein, when the method implements the etching by the other from among the front or the back exposed surfaces of the substrate, until reaching the via, the selecting the at least one via to be etched from among the plurality of vias comprises applying on the other front or back exposed surface of the substrate, a mask comprising openings located in vertical alignment with the at least one via to be etched, and the method further comprising etching so as to reach the at least one via to be etched.

40. The method according to claim 36, wherein the depositing the electrically conductive or semiconductive member is configured so as to further cover at least one portion of the front and/or the back exposed surface of the substrate by an electrically conductive or semiconductive layer.
